(19) United States
(12) Patent Application Publication
(10) Pub. No.: US 2026/0068144 A1
(43) Pub. Date: Mar. 5, 2026

(54) 4F2 DRAM WITH BACKSIDE CONTACT

(71) Applicant: Applied Materials, Inc., Santa Clara, CA (US)

(72) Inventors: Tong LIU, Folsom, CA (US); Ashish PAL, San Ramon, CA (US); Sony VARGHESE, Manchester, MA (US); Gregory COSTRINI, Flanders, NJ (US); El Mehdi BAZIZI, San Jose, CA (US); Balasubramanian PRANATHARTHIHARAN, San Jose, CA (US)

(73) Assignee: Applied Materials, Inc., Santa Clara, CA (US)

(21) Appl. No.: 18/824,479

(22) Filed: Sep. 4, 2024

(51) Int. Cl. H10B 12/00

(52) U.S. Cl. CPC H10B 12/50; H10B 12/09; H10B 12/315

(57) ABSTRACT

The present technology includes methods, devices and systems for forming advanced memory structures, and devices therefrom. Devices include a transistor having one or more bit lines arranged in a first horizontal direction, one or more word lines arranged in a second horizontal direction, and one or more channels extending in a vertical direction that is generally orthogonal to the first horizontal direction and the second horizontal direction. Devices include a capacitor overlying the transistor, where the transistor extends from a first end of a DRAM array to the capacitor, and the capacitor extends from the transistor to a second end of the DRAM array. Devices include a periphery transistor having a contact side and a second side, where the contact side of the periphery transistor is bonded to the first end of the DRAM array and one or more landing pads formed between the transistor and the periphery transistor.

### TECHNICAL FIELD

This disclosure generally describes designs for advanced DRAM memory devices, such as 4F² dynamic random-access memory (DRAM) arrays, 6F² DRAM arrays, 3D DRAM, and other advanced memory devices. More specifically, this disclosure describes advanced memory arrays with backside contacts to the powerline and/or signal line.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density. As devices continue to scale down, there is a desire to reduce the space occupied by contacts. However, advanced design schemes often exhibit complex features, making contact formation difficult. Thus, there is a need in the industry to improve one or more features of advanced memory devices.

### BRIEF SUMMARY

The present technology is generally directed to vertical cell dynamic random-access memory (DRAM) structures. Structures include a transistor having one or more bit lines arranged in a first horizontal direction, one or more word lines arranged in a second horizontal direction, and one or more channels extending in a vertical direction that is generally orthogonal to the first horizontal direction and the second horizontal direction such that the one or more bit lines intersect with a source/drain region of the one or more channels, and the one or more word lines intersect with a gate region of the one or more channels. Structures include a capacitor overlying the transistor, where the transistor extends from a first end of a DRAM array to the capacitor, and the capacitor extends from the transistor to a second end of the DRAM array. Structures include a periphery transistor having a contact side and a second side, wherein the contact side of the periphery transistor is bonded to the first end of the DRAM array. Structures include one or more landing pads formed between the transistor and the periphery transistor, where one or more backside contacts are formed extending from the periphery transistor to the one or more landing pads.

In embodiments, the DRAM array includes an array area bounded by exterior edges of one or more exterior DRAM cells, wherein the one or more landing pads are formed within the array area. Furthermore, in embodiments, the one or more landing pads are formed directly between the transistor and the periphery transistor. In more embodiments, the one or more landing pads include at least one bit line landing pad electrically connected to the bit line and at least one word line landing pad electrically connected to the word line, where at least one backside contact extends to each of the at least one bit line landing pad and the at least one word line landing pad. Additionally or alternatively, in embodiments, the periphery transistor has a thickness of less than or about 2 μm. Embodiments include where the one or more backside contacts have a length of less than or about 2 μm. In yet more embodiments, the one or more backside contacts have a length of less than or about 1.5 μm. In further embodiments, the one or more backside contacts have a length of less than or about 1 μm. In embodiments, an aspect ratio of the one or more backside contacts is less than or about 10. Moreover, in embodiments, a plate contact extends along the second end of the DRAM cell, where a plate contact electrically connects the plate to the periphery transistor.

The present technology is also generally directed to methods of forming a vertical cell dynamic random-access memory (DRAM) structure. Methods include forming one or more landing pads at a backside of a DRAM array, where the DRAM array includes a frontside opposite the backside, a capacitor extends from the frontside to a transistor, and the transistor extends from the capacitor to the backside. Methods include bonding a contact side of a periphery transistor to the backside of a DRAM array. Methods include etching one or more contact vias through the periphery transistor to the one or more landing pads and depositing a conductive material in the one or more vias.

In embodiments, the transistor includes: one or more bit lines arranged in a first horizontal direction, one or more word lines arranged in a second horizontal direction, and one or more channels extending in a vertical direction that is generally orthogonal to the first horizontal direction and the second horizontal direction such that the one or more bit lines intersect with a source/drain region of the one or more channels, and the one or more word lines intersect with a gate region of the one or more channels. Moreover, in embodiments, methods include bonding the frontside of the DRAM array to a carrier and reducing a thickness of the periphery transistor. In further embodiments, the thickness is reduced by greater than or about 20%. Embodiments include where the one or more landing pads are formed within an array area, where the array area is bounded by exterior edges of one or more exterior DRAM cells of the DRAM array. Additionally or alternatively, methods include forming a plate at a frontside of the DRAM Array. In embodiments, methods include etching one or more plate contacts between the periphery transistor and the plate.

The present technology is also generally directed to 4F² dynamic random-access memory (DRAM) structures. Structures include a transistor, a capacitor overlying the transistor, where the transistor extends from a first end of a 4F² DRAM array to the capacitor, and the capacitor extends from the transistor to a second end of the 4F² DRAM array. Structures include a CMOS transistor having a contact side and a second side, where the contact side of the CMOS transistor is bonded to the first end of the 4F² DRAM array and one or more landing pads formed between the transistor and the CMOS transistor. Structure include where one or more backside contacts are formed extending from the CMOS transistor to the one or more landing pads.

In embodiments, the 4F² DRAM array includes an array area bounded by exterior edges of one or more exterior DRAM cells, wherein the one or more landing pads are formed within the array area. In embodiments, the one or more backside contacts have a length of less than or about 1.5 μm.

Such technology may provide numerous benefits over conventional systems and techniques. For example, the processes and systems discussed herein may allow for the reduction in contact length, improving the size and electrical properties of the device. Additionally, the processes and systems may allow for the signal line and power line contacts to be located beneath the array, providing for decreases in size of the array. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIG. 3A shows a schematic view of a semiconductor structure according to embodiments of the present technology.

FIG. 3B shows a schematic view of a semiconductor structure according to embodiments of the present technology.

FIG. 3C shows a schematic view of a semiconductor structure according to embodiments of the present technology.

FIG. 3D shows a schematic view of a semiconductor structure according to embodiments of the present technology.

FIG. 3E shows a schematic view of a semiconductor structure according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Advanced semiconductor packages include multiple devices disposed in one or more layers of the package. These devices may all be connected to one or more networks of metal lines or vias to transmit power and data signals to and from the various devices. As the packages have become more complex, the networks have also become more complex, creating issues with routing, signal integrity, and other such issues. As both power signals and data signals are fundamentally electrical current provided via metal pathways, one may interfere with the other.

In a typical package, a device layer (or layers) may be disposed on a substrate layer (e.g., a silicon wafer) or may include two or more substrates bonded together after fabrication of one or more devices thereon. A metal layer of various pathways and vias may then be formed on or between the device layer(s). Some of the various pathways and vias may be used to provide power to the devices within the device layers, and others may be used to transmit data to and from the various devices. As the complexity of the device(s) continues to increase, the space needed to route contacts to the power line and/or signal line and the space needed to route the signals compete with one another. Furthermore, as the contact length and/or aspect ratio of the contact(s) increases, the resistivity increases and can make the power delivered and/or signal received to/from the device(s) less reliable. This is particularly problematic as devices become more complex, such as in advanced DRAM memory devices, such as 4F² dynamic random-access memory (DRAM) arrays, 6F² DRAM arrays, 3D DRAM, and other advanced memory devices, as there is a competing desire to continue to reduce cell and array size.

For instance, DRAM chip bit densities have historically been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F² DRAM are greatly reduced as compared to 6F². This is due at least in part to the fact that in the 4F² DRAM scheme, the capacitor and bit line are located at two ends of a vertical cell transistor, instead of tightly packed on the same side as in 6F² DRAM. However, this same architecture makes the formation of landing pads and contacts problematic.

Due to the vertical alignment of the cell transistor, contacts between the capacitor and periphery transistor must transverse the entirety of the height of the transistor cell, resulting in contacts greater than 1.7 μm in length. This results in the formation of very high aspect ratio (e.g. an aspect ratio of greater than 40) vias, as the width of the contact, and therefore the critical dimension of the contact, is limited due to width of the array. Thus, due to the height required, conventional systems have not been able to decrease the contact width, as it would exceed the aspect ratios possible for through-via formation. In addition, the location and arrangement of the signal line and/or power line in existing 4F² DRAM hinders placement of contact pads below the array. Thus, existing 4F² DRAM arrays have landing pads spaced laterally outside of the respective cells in order to prevent issues with contacts extending though the power and/or signal line, resulting in an arrangement of the landing pads extending around the exterior of the array. This causes an increase in the cell and array size (e.g. two times the width of the contact in both the length and width of the array), which is problematic when trying to reduce cell size.

The present technology overcomes these and other problems by bonding a periphery transistor, such as a CMOS transistor in the case of a 4F² DRAM array, to the backside of the DRAM array (e.g. a bit line side of the DRAM array) and forming one or more contacts through the periphery transistor. Such an arrangement significantly reduces contact length, as the transistor of the DRAM array is disposed adjacent to the DRAM array backside (e.g. the DRAM transistor is disposed between the capacitor and the periphery transistor). For instance, in embodiments, arrangements according to the present technology may result in contact heights or less than 1 μm. In addition, the backside contacts of the present technology allow for landing pads of the powerline and/or signal line to be located vertically between the DRAM array transistor and the periphery transistor (e.g. within an array area), instead of around the periphery of the DRAM array, further reducing the contact length and array size. In addition, the processes and methods of the present technology also utilize silicon etching through the periphery transistor, which may allow for lower temperature and improved etching than existing dielectric etching through the DRAM array.

Although the remaining disclosure will routinely identify specific deposition and etch processes utilized for forming vertical cell access array transistors (VCAATs), such as a 4F² DRAM device, it will be readily understood that the systems and methods are equally applicable to other memory devices, particularly vertically oriented devices, as well as processes for forming such devices. Accordingly, the technology should not be considered to be so limited as for use with these specific devices or systems alone. The disclosure will discuss one possible semiconductor device that may include one or more components, utilizing one or more power lines and/or signal lines according to embodiments of the present technology before additional variations and adjustments to this apparatus according to embodiments of the present technology are described.

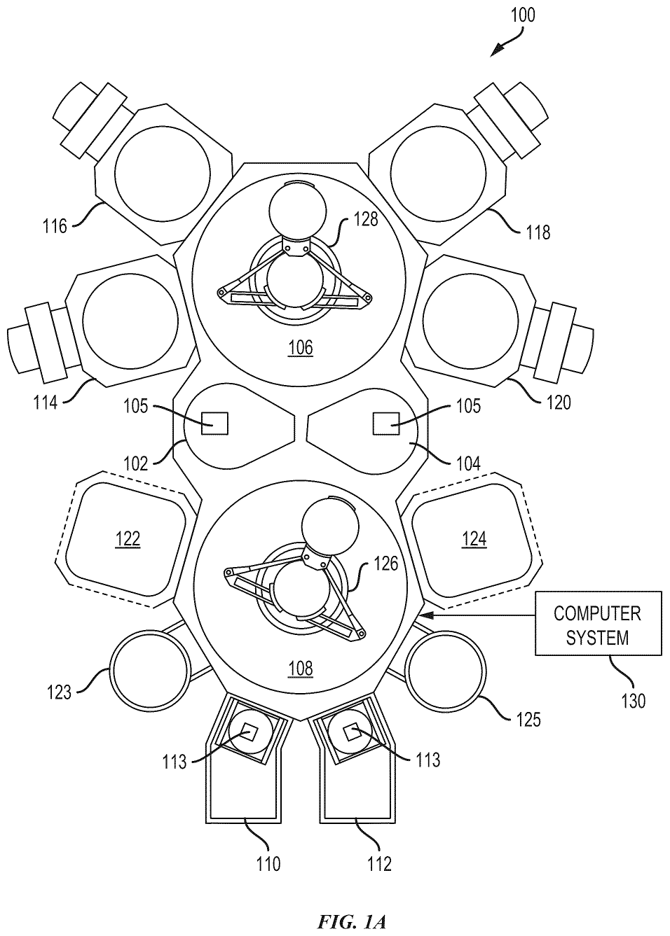

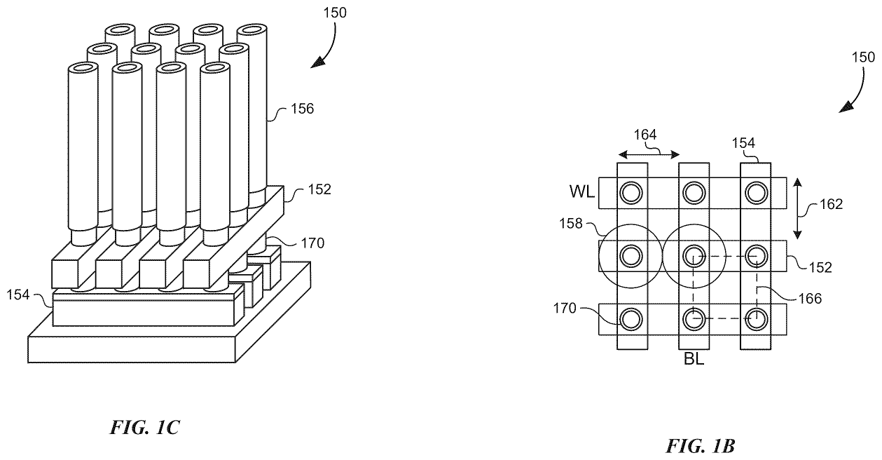

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108 and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general-purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and 1C illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor, which may be referred to as a vertical pillar transistor or vertical column transistor. A channel material for the transistor may be formed from a single-crystalline silicon, poly-crystalline silicon, amorphous silicon, silicon carbide, silicon germanium, germanium, an oxide semiconductor, including indium gallium zinc oxide, 2D materials including molybdenum disulfide, gallium nitride, carbon nanotubes, graphene, boron arsenide, combinations thereof, or any other substrates discussed in greater detail herein. Furthermore, dopants may be introduced based upon the device need, for any one or more of the materials discussed herein. This silicon channel may be formed by etching the substrate, as shown in the illustrated embodiments, or may be deposited onto the substrate, depending upon the desired device.

Substrate materials may include bulk substrates, epitaxially grown substrates, silicon, silicon germanium (SiGe), silicon on insulator (SOI), silicon germanium on insulator (SGOI), indium antimonide, lead telluride compound, indium arsenide, indium phosphide, and/or gallium arsenide, as well as any one or more substrate materials discussed above, on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate includes a semiconductor material, e.g., silicon (Si), carbon (C), germanium (Ge), silicon germanium (SiGe), germanium tin (GeSn), other semiconductor materials, or any combination thereof. In one or more embodiments, the substrate includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

Thus, in embodiments, the semiconductor or channel material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors and capacitors in a rectangular generally orthogonal grid pattern (where “generally orthogonal” may be within about 10° from orthogonal, such as less than or about 7.5°, such as less than or about 5°, such as less than or about 2.5°, such as less than or about 1° from orthogonal, or any ranges or values therebetween, where “generally” may be utilized to similarly vary “vertical”, “horizontal” and the like), it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F² memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

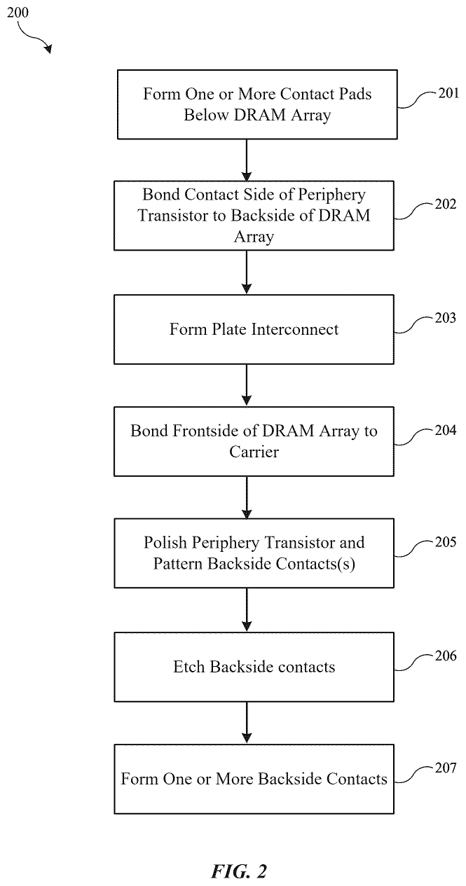

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically, it should be understood that the other orientation from bit line to word line side may be utilized, as well as other orientations for non-vertical cell transistors.

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in the Figures, the illustrations of which will be described in conjunction with the operations of method 200. It is to be understood that the Figures illustrate only partial schematic views, and a semiconductor substrate may include further components as illustrated in the figures, as well as alternative components, of any size or configuration that may still benefit from aspects of the present technology.

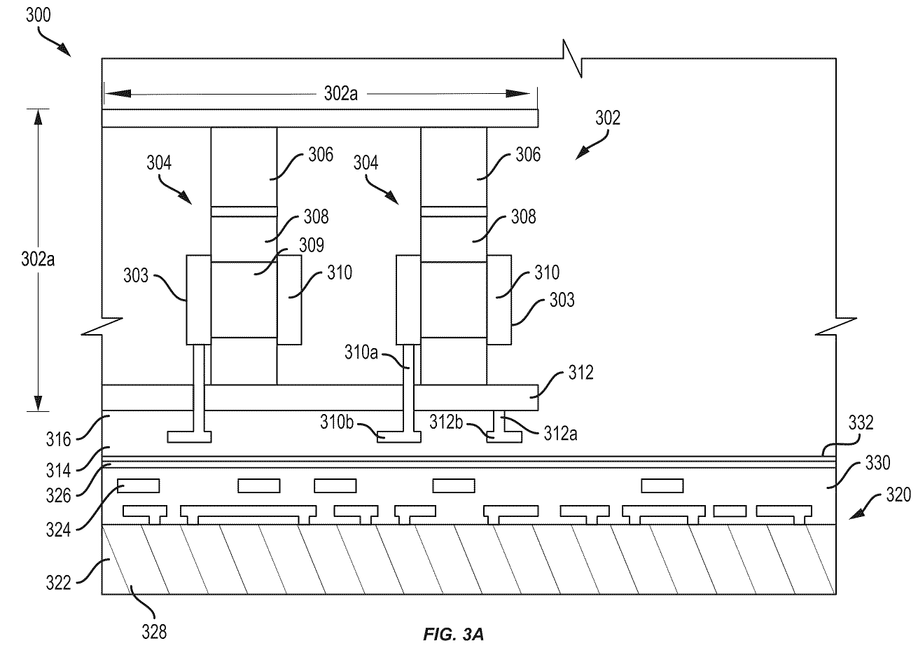

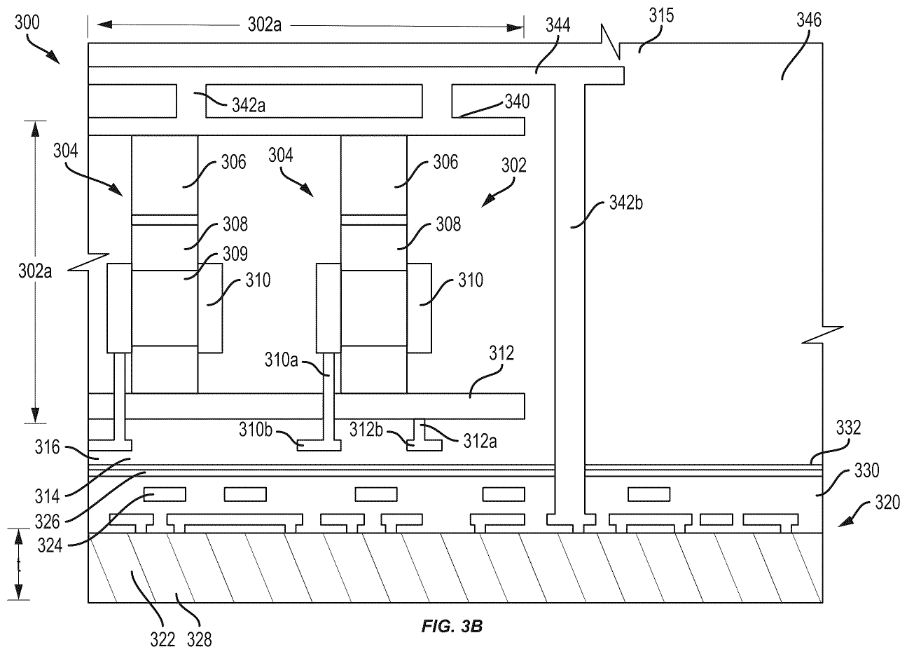

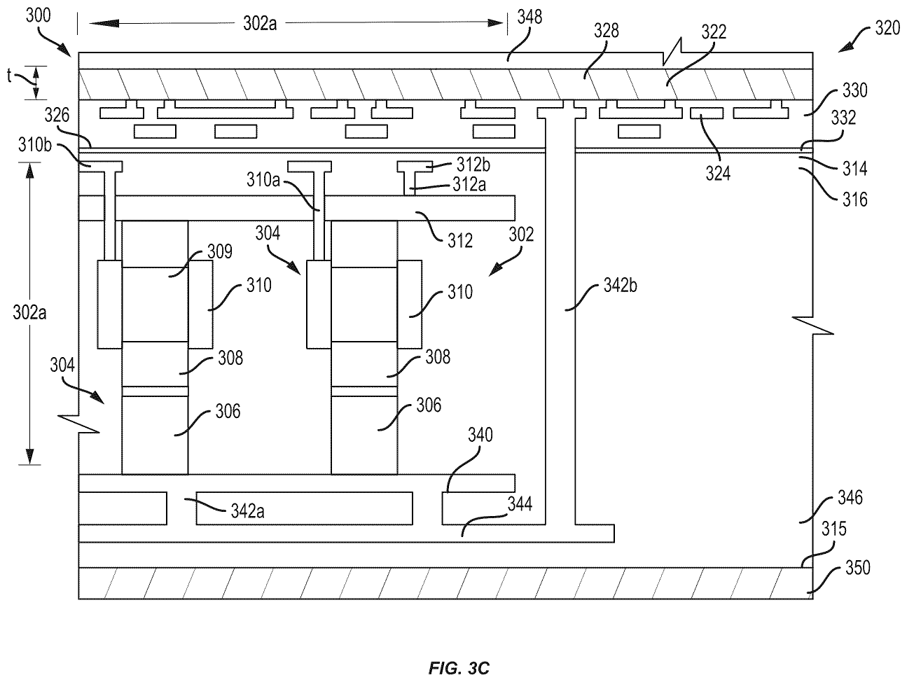

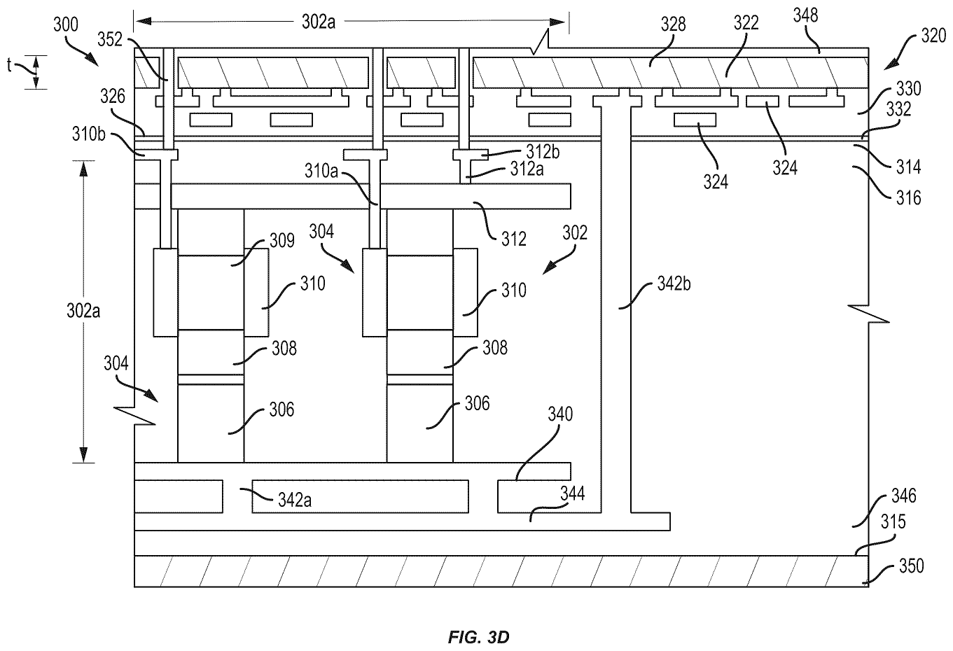

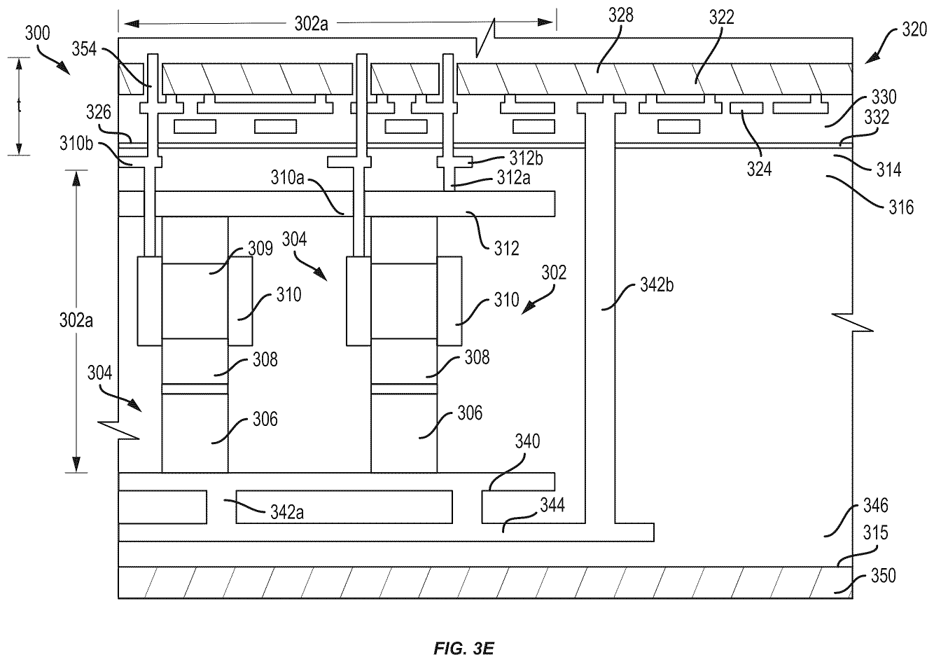

Method 200 may or may not involve optional operations to develop the semiconductor structure to a particular fabrication operation. It is to be understood that method 200 may be performed on any number of semiconductor structures 300 as illustrated in the Figures, including exemplary structures on which a selective deposition material may be formed. As illustrated in FIG. 3A semiconductor structure 300 may include a DRAM array 302 formed overlying a substrate during semiconductor processing.

Moreover, while various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

As illustrated in FIG. 3A, structure 300 is provided that contains two or more DRAM cells 304, each containing a capacitor 306 and a transistor 308. The DRAM cell 304 may be or include a 4F² DRAM cell discussed above. Thus, in embodiments, the capacitor 306 and/or transistor 308 may be or include any one of the vertical cell capacitors or transistors discussed above. Nonetheless, as illustrated, in embodiments, each transistor 308 may contain a channel 309 and be electrically connected to one or more word lines 310 and one or more bit lines 312. In embodiments, the one or more word lines 310 and/or one or more bit lines 312 may be or include a bit line and/or word line discussed above, such as when the DRAM array 302 is a 4F² DRAM array.

Nonetheless, as illustrated, in embodiments, the methods and devices discussed herein, such as a 4F² DRAM array, may have cells containing one or more word line contacts 310a and one or more word line landing pads 310b and/or one or more bit line contacts 312a and one or more bitline landing pads 312b. Unlike conventional devices and systems, the contacts 310a, 312a and landing pads 310b, 312b are formed between the bit line 312 and a backside 314 of the DRAM array 302 (and/or the respective DRAM cell 304), such as within array area 302a. In embodiments, the array area 302a may be located within an area bounded by exterior edges 303 of outermost DRAM cells 304 of the respective DRAM array 302 (e.g. the terminals of the bit line and/or word line for the respective array). Thus, while only two DRAM cells 304 are illustrated herein, it should be understood that arrays containing a greater array area and number of cells is contemplated herein. Namely, in conventional systems, the landing pads are formed around a periphery of the DRAM array 302 (e.g. laterally outwards of the DRAM array 302/DRAM array area 302a). Thus, the devices and systems of the present technology may provide for a reduced array area due at least in part to their location below, such as directly below, the DRAM array 302 and/or array area 302a.

Thus, in embodiments, operation 201 may include etching one or more contact holes through backside 314 terminating at the respective word line 310 or bit line 312. Advantageously, the one or more bit line and/or word line contact holes or vias may be disposed between, such as directly between, the backside 314 and the array 302, such as within array area 302. In embodiments, formation of the contact holes may include patterning a mask layer over an exterior surface of backside 314, followed by etching of the one or more contact holes. As discussed above, advantageously, due to the location of the contact holes, the one or more bit line and/or word line contact holes may have a low aspect ratio, such as less than or about 8, less than or about 7.5, less than or about 7, less than or about 6.5, less than or about 6, less than or about 5.5, less than or about 5, less than or about 4.5, less than or about 4, less than or about 3.5, less than or about 3, less than or about 2.5, or any ranges or values therebetween. After formation of the one or more contact holes, the contact holes may be filled with a conductive material, at operation 201, forming the one or more bit line contacts 312a, word line contacts 310a, and conductive material that will form bit line landing pad(s) 312b and word line contact pad(s) 310b. In embodiments, the filling may include a CVD process, as well as other deposition processes discussed above.

Nonetheless, operation 201 may further include patterning and etching the conductive material in order to form the one or more bit line landing pad(s) 312b and word line landing pad(s) 310b, as illustrated in FIG. 3A. Thus, after patterning the landing pads, the remaining conductive material is removed, such as by etching, leaving the one or more bit line landing pad(s) 312b and word line landing pad(s) 310b, isolated from adjacent structures. As illustrated in FIG. 3A, a dielectric material 316 may be deposited over the one or more bit line landing pad(s) 312b and word line landing pad(s) 310b, preparing the structure for bonding to a peripheral device.

In embodiments, the conductive material may include titanium nitride, titanium silicon nitride, titanium aluminide, titanium aluminum nitride, polycrystalline silicon, amorphous silicon, molybdenum nitride, molybdenum silicide, titanium, ruthenium, tungsten, molybdenum, tantalum nitride, tungsten nitride, tungsten silicide, tungsten carbon nitride, tungsten silicon nitride, niobium nitride, titanium aluminum nitride, titanium silicon nitride, tantalum silicon nitride, ruthenium titanium nitride, lanthanum nitride, or a combination thereof. In embodiments, the conductive materials may include tungsten, titanium nitride, or a combination thereof.

The semiconductor structure 300 also includes a periphery transistor 320, which may be or include a CMOS transistor, in embodiments. While it should be clear that the box representing the periphery transistor component(s) 322 has been simplified to include one or more periphery transistor components, it should be understood that box 322 may be or include any one or more periphery transistor structures, such as a CMOS transistor, or elements thereof, in embodiments. Nevertheless, as illustrated, the periphery transistor 320 may contain one or more contacts 324 formed on or adjacent to a first side 326 of the periphery transistor, opposite a second side 328, where the one or more periphery transistor components 322 may be formed between the one or more contacts 324 and second side 328. Thus, in embodiments, the first side 326 may be referred to as the “contact side” of the periphery transistor 320, as the one or more contacts 324 are formed at or adjacent to the first side 326 (e.g. the contacts 324 may be formed between the one or more periphery transistor components 322 and first side 326 such that only one or more dielectric materials 330 may be disposed between the one or more contacts 324 and first side 326). Namely, in embodiments, one or more dielectric materials 330 may be formed over the one or more contacts 324, so as to provide for oxide bonding to DRAM array 302. In embodiments, the one or more contacts 324 may be any one or more of the conductive materials discussed above, or may be or include copper. Namely, the present technology has found that the back end of line processes may be performed prior to bonding or alternatively, may be completed after bonding of the DRAM array to the periphery array.

In embodiments, dielectric material(s) 316 and/or 330 may be or include in silicon oxide, silicon oxynitride, silicon oxycarbonitride, silicon carbonitride, titanium oxide, aluminum oxide, tungsten oxide, zirconium oxide, and combinations thereof. Namely, in embodiments, the dielectric materials may be selected so as to be compatible with oxide bonding, such as hybrid bonding, fusion bonding, or a combination thereof.

Still referring to FIG. 3A, methods according to the present technology include bonding a first side 326 of the periphery transistor 320 to a backside 314 of the DRAM array 302, at operation 202. Bonding may include forming an oxide bond 332 between the periphery transistor 320 and DRAM array 302, via one or more oxide bonding methods. In embodiments, the bonding may include fusion bonding, hybrid bonding, or a combination thereof. Namely, unlike conventional systems, the present technology has unexpectedly found that by bonding the first side 326 (e.g. the contact side) of the periphery transistor 320 to a backside 314 of the DRAM array 302, not only can the interconnect contact length and periphery area be drastically reduced, but etching of the interconnect vias may be simplified, due to the etching of the periphery transistor 320, which is predominantly silicon, as compared to dielectric materials of the DRAM array 302. In addition, such a method may also provide for the use of low resistance metals for the bit line, where previously, bit lines were restricted to doped silicon.

Referring next to FIG. 3B, one or more plate contacts 342 and plate interconnects 344 may be formed at operation 203. While so far it has been discussed that plate 340 and capacitor 306 are formed prior to bonding the periphery transistor 320 to a backside 314 of the DRAM array 302, it should be clear that, in embodiments, the plate 340, capacitor 306, or a combination thereof, may be formed after bonding the periphery transistor 320 to a backside 314 of the DRAM array 302. Nonetheless, in embodiments, one or more vias that will form plate contacts 342 are etched from the frontside 315 of the DRAM array 302. Advantageously, unlike the bit line or word line contacts, the plate contact is not space constrained. Therefore, a relatively wide via may be utilized, preventing the necessity for high aspect ratio plate contacts. Thus, the plate contact may be positioned through an entirety of the height of the DRAM array 302 without facing space constraints, unlike bit line and word line contacts in conventional systems. After formation of the one or more vias, the vias may be filled with a conductive material, such as one or more of the conductive materials discussed above, forming the one or more plate contacts 342. In embodiments, the filling may be or include one or more of the deposition processes discussed above, such as a CVD process, in embodiments.

In embodiments, a portion of the plate contacts 342 may be formed between plate 340 and a frontside interconnect 344. The frontside interconnect 344 may be formed during deposition of the conductive material forming plate contact 342. The frontside interconnect 344 may extend laterally outward from the DRAM array area 302a, allowing for case of connection to a frontside plate contact 342b. In embodiments, the frontside plate contact 342b may have a greater height (e.g. distance extending from frontside 315 towards backside 314, and through backside 314 for some components), than plate contacts 342a, and may therefore also have a larger critical dimension than plate contacts 342a, in order to maintain the necessary aspect ratio. In embodiments, after formation of the plate contact(s) 342a and frontside plate contact(s) 342b, the frontside interconnect 344 may be patterned and etched, forming the frontside interconnect 344 shape and structure as illustrated in FIG. 3B. After etching, the frontside interconnect 344 may be encapsulated in a dielectric material 346, such as one or more of the dielectric materials discussed above.

As illustrated in FIG. 3C, the semiconductor structure 300 may be bonded to a carrier 350 at operation 204. In embodiments, the frontside 315 of the DRAM array may be bonded to the carrier 350, leaving the second side 328 of the periphery transistor 320 externally accessible. In embodiments, the carrier 350 may be or include a secondary substrate. Nevertheless, the carrier 350 may be glued, taped, or otherwise bonded to the frontside 315 of DRAM array 302, to act as a secondary “substrate” during backside processing. In embodiments, the carrier may include silicon, quartz, sapphire, glass, indium phosphide, plastic and plastic based materials, combinations thereof, and the like. The carrier 350 may contain one or more device components, such as one or more transistors, one or more metal interconnects and lines, one or more control circuits, one or more storage devices, or the like. It may also contain none of such and act purely as structural support. Furthermore, it should be clear that in embodiments, the carrier may be introduced prior to or after flipping. Thus, while illustrated in a flipped configuration, it should be clear that the carrier 350 may be introduced prior to flipping (e.g. the backside is now disposed vertically above the frontside).

At operation 205, the second side 328 of the periphery transistor 320 may be polished, or otherwise etched, reducing the thickness t of the periphery transistor. Advantageously, the periphery transistor 320 may be polished or otherwise thinned such that a total thickness t is less than or about 2 μm, less than or about 1.9 μm, less than or about 1.8 μm, less than or about 1.7 μm, less than or about 1.6 μm less than or about 1.5 μm, less than or about 1.4 μm, less than or about 1.3 μm, less than or about 1.2 μm, less than or about 1.1 μm, less than or about 1.0 μm, less than or about 0.9 μm, less than or about 0.8 μm, less than or about 0.7 μm, less than or about 0.6 μm, less than or about 0.5 μm, less than or about 0.4 μm, or such as greater than 0.3 μm, greater than or about 0.4 μm, or any ranges or values therebetween. By reducing a thickness of the periphery transistor 320, the contact length may be further controlled and reduced in height. In embodiments, the reduction may result in an overall reduction in thickness of the silicon substrate of the periphery transistor of greater than or about 20%, greater than or about 30%, greater than or about 40%, greater than or about 50%, greater than or about 60%, greater than or about 70%, greater than or about 80%, greater than or about 90%, or any ranges or values therebetween.

After reducing a thickness of the periphery transistor, a hard mask layer 348 may be formed over the second side 328 of the periphery transistor. The hard mask layer 348 may be or include any one or more of the dielectric materials discussed above.

Referring next to FIG. 3D, one or more contact vias 352 may be etched or otherwise formed from and through a second side 328 of the periphery transistor 320, to the respective bit line landing pad(s) 312b and/or word line landing pad(s) 310b, at operation 206. In embodiments, a patterning mask may first be applied over hard mask 348 to assist with etching. Nonetheless, as illustrated, the one or more contact vias 352 may intersect one or more periphery transistor contacts 324 while also terminating at the one or more bit line landing pad(s) 312b and/or word line landing pad(s) 310b. While the figure illustrates a single step etch operation, it should be understood that the etch operation to form the one or more contact vias 352 at operation 206 may include one or more steps. For instance, in embodiments, a first portion of the vias 352 extending from second side 328 to the one or more periphery transistor contacts 324 may be etched. An optional isolation material, such as a dielectric material may be formed in the first via portion in order to isolate the via from the periphery transistor components 322. However, in embodiments, no isolation material may be necessary. Nonetheless, a bottom punch or other etch operation, may be utilized to etch through the one or more periphery transistor contacts 324, at which point the remaining portion or second portion extending for the one or more periphery transistor contacts 324 to the one or more bit line landing pad(s) 312b and/or word line landing pad(s) 310b, may be formed. Nonetheless, as discussed above, in embodiments, the etch process may also be a one step and/or two step process.

Notwithstanding the method utilized to form the one or more vias 352, after formation, the vias 352 may be filled with a conductive material to form the one or more backside contacts 354 at operation 207, as illustrated in FIG. 3E. The conductive material may be or include any one or more of the conductive materials discussed above, which may be deposited with one or more deposition methods. In embodiments, the conductive material may be or include titanium nitride and/or the deposition method may include chemical vapor deposition.

Advantageously, due to the arrangement of the structure of the pending claims, the backside contacts 354 may have a length/between a second side 328 of the periphery transistor to the respective one of the or more bit line landing pad(s) 312b and/or word line landing pad(s) 310b, of less than or about 2 μm, less than or about 1.9 μm, less than or about 1.8 μm, less than or about 1.7 μm, less than or about 1.6 μm less than or about 1.5 μm, less than or about 1.4 μm, less than or about 1.3 μm, less than or about 1.2 μm, less than or about 1.1 μm, less than or about 1.0 μm, less than or about 0.9 μm, less than or about 0.8 μm, less than or about 0.7 μm, less than or about 0.6 μm, less than or about 0.5 μm, less than or about 0.4 μm, or such as greater than 0.3 μm, greater than or about 0.4 μm, or any ranges or values therebetween. In embodiments, the reduction may result in an overall reduction in thickness of greater than or about 20%, greater than or about 30%, greater than or about 40%, greater than or about 50%, greater than or about 60%, or any ranges or values therebetween, in the contact length, as compared to a frontside contact. Furthermore, the aspect ratio of the backside contact 354 may be about 15 or less, such as less than or about 14, less than or about 13, less than or about 12, less than or about 11, less than or about 10, less than or about 9, less than or about 8, or any ranges or values therebetween.

It should be appreciated that the specific steps illustrated in the figures provide particular methods of forming 4F² DRAM arrays according to various embodiments but are also applicable to other advanced memory structures as discussed herein. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have beeen described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A vertical cell dynamic random-access memory (DRAM) structure, comprising:
a transistor comprising
one or more bit lines arranged in a first horizontal direction;
one or more word lines arranged in a second horizontal direction;
one or more channels extending in a vertical direction that is generally orthogonal to the first horizontal direction and the second horizontal direction such that the one or more bit lines intersect with a source/drain region of the one or more channels, and the one or more word lines intersect with a gate region of the one or more channels;
a capacitor overlying the transistor, wherein the transistor extends from a first end of a DRAM array to the capacitor, and the capacitor extends from the transistor to a second end of the DRAM array;
a periphery transistor having a contact side and a second side, wherein the contact side of the periphery transistor is bonded to the first end of the DRAM array; and
one or more landing pads formed between the transistor and the periphery transistor;
wherein one or more backside contacts are formed extending from the periphery transistor to the one or more landing pads.

2. The structure of claim 1, wherein the DRAM array comprises an array area bounded by exterior edges of one or more exterior DRAM cells, wherein the one or more landing pads are formed within the array area.

3. The structure of claim 1, wherein the one or more landing pads are formed directly between the transistor and the periphery transistor.

4. The structure of claim 1, wherein the one or more landing pads comprise at least one bit line landing pad electrically connected to the bit line and at least one word line landing pad electrically connected to the word line, wherein at least one backside contact extends to each of the at least one bit line landing pad and the at least one word line landing pad.

5. The structure of claim 1, wherein the periphery transistor has a thickness of less than or about 2 μm.

6. The structure of claim 1, wherein the one or more backside contacts have a length of less than or about 2 μm.

7. The structure of claim 6, wherein the one or more backside contacts have a length of less than or about 1.5 μm.

8. The structure of claim 7, wherein the one or more backside contacts have a length of less than or about 1 μm.

9. The structure of claim 1, wherein an aspect ratio of the one or more backside contacts is less than or about 10.

10. The structure of claim 1, further comprising a plate contact extending along the second end of the DRAM cell, wherein a plate contact electrically connects the plate to the periphery transistor.

11. A method of forming a vertical cell dynamic random-access memory (DRAM) structure, comprising:
forming one or more landing pads at a backside of a DRAM array, wherein the DRAM array comprises a frontside opposite the backside, wherein a capacitor extends from the frontside to a transistor, and the transistor extends from the capacitor to the backside;
bonding a contact side of a periphery transistor to the backside of a DRAM array;
etching one or more contact vias through the periphery transistor to the one or more landing pads; and
depositing a conductive material in the one or more vias.

12. The method of claim 11, wherein the transistor comprises:
one or more bit lines arranged in a first horizontal direction;
one or more word lines arranged in a second horizontal direction; and
one or more channels extending in a vertical direction that is generally orthogonal to the first horizontal direction and the second horizontal direction such that the one or more bit lines intersect with a source/drain region of the one or more channels, and the one or more word lines intersect with a gate region of the one or more channels.

13. The method of claim 11, further comprising, bonding the frontside of the DRAM array to a carrier and reducing a thickness of the periphery transistor.

14. The method of claim 13, wherein the thickness is reduced by greater than or about 20%.

15. The method of claim 11, wherein the one or more landing pads are formed within an array area, wherein the array area is bounded by exterior edges of one or more exterior DRAM cells of the DRAM array.

16. The method of claim 11, further comprising forming a plate at a frontside of the DRAM Array.

17. The method of claim 16, further comprising etching one or more plate contacts between the periphery transistor and the plate.

18. A 4F² dynamic random-access memory (DRAM) structure, comprising:
a transistor;
a capacitor overlying the transistor, wherein the transistor extends from a first end of a 4F² DRAM array to the capacitor, and the capacitor extends from the transistor to a second end of the 4F² DRAM array;
a CMOS transistor having a contact side and a second side, wherein the contact side of the CMOS transistor is bonded to the first end of the 4F² DRAM array; and
one or more landing pads formed between the transistor and the CMOS transistor;
wherein one or more backside contacts are formed extending from the CMOS transistor to the one or more landing pads.

19. The structure of claim 18, wherein the 4F² DRAM array comprises an array area bounded by exterior edges of one or more exterior DRAM cells, wherein the one or more landing pads are formed within the array area.

20. The structure of claim 18, wherein the one or more backside contacts have a length of less than or about 1.5 μm.
